(19) United States
(12) Patent Application Publication
(10) Pub. No.: US 2021/0407974 A1
(43) Pub. Date: Dec. 30, 2021

(54) SPLICED DISPLAY SCREEN, MANUFACTURING METHOD THEREOF, AND DISPLAY DEVICE

(71) Applicant: Shenzhen China Star Optoelectronics Semiconductor Display Technology Co., Ltd., Shenzhen, Guangdong (CN)

(72) Inventor: Bei Jiang, Shenzhen (CN)

(73) Assignee: Shenzhen China Star Optoelectronics Semiconductor Display Technology Co., Ltd., Shenzhen, Guangdong (CN)

(21) Appl. No.: 16/652,263

(22) PCT Filed: Jan. 10, 2020
(86) PCT No.: PCT/CN2020/071324

§ 371 Date: Mar. 30, 2020

(30) Foreign Application Priority Data
Dec. 30, 2019 (CN) 201911392332.8

(51) Int. Cl. H01L 25/16

(52) U.S. Cl. CPC H01L 25/167; H01L 25/162

(57) ABSTRACT

A spliced display screen, a manufacturing method thereof, and a display device are provided. The spliced display screen includes at least two display panels. Each of the display panels has a display area and a non-display area, and the display area has a main display area and a flexible display area. In two adjacent display panels, the flexible display area of one of the display panels covers the non-display area of the other one of the display panels, and an edge of the flexible display area of the one of the display panels is seamlessly abutted to an edge of the non-display area of the other one of the display panels.

### FIELD OF DISCLOSURE

The present disclosure relates to the field of display equipments, and particularly relates to a spliced display screen, a manufacturing method thereof, and a display device.

### BACKGROUND OF DISCLOSURE

Light emitting diode (LED) or organic light emitting diode display technology is a display method that directly uses the LEDs as pixels. A color LED display screen is composed of three-color (red, green, and blue) LEDs as basic light emitting elements, and is arranged in a lattice manner. The LED display screen is usually composed of a display module, a control system, and a power supply system. The control system controls on and off of the LED to emit different colors of light, thereby forming images. According to the difference in dot pitches, the LED display technology can be divided into small-pitch LED display technology, mini-LED display technology, and micro-LED display technology.

A small-pitch LED display screen refers to an indoor LED display screen with LED dot pitches below P2.5, mainly comprising LED display screen products with P2.5, P2.0, P1.8, or P1.5. Both the micro-LED and the mini-LED are based on tiny LED crystal particles used as pixel light emitting points. The difference is that, the micro-LED uses 1 to 10 microns LED crystals to achieve the display screen of 0.05 micrometers or smaller pixel particles, and the mini-LED uses tens of micron-level LED crystals to achieve the display screen of 0.5 to 1.2 micrometers pixel particles.

Today, small-pitch LED large-size display screens have been used in some advertising or decorative walls. However, the pixel size thereof is large, which directly affects the fineness of the display image. When the viewing distance is close, the display effect is unsatisfactory. Although the micro-LEDs are far superior to the small-pitch LEDs in contrast and viewing angles, the micro-LEDs have not made a breakthrough in key technologies and equipments. Thus, mass production cannot be achieved in a short time. The mini-LEDs have the characteristics of the small-pitch LEDs, such as high efficiency, high brightness, high reliability, and fast response times, and the technique thereof is simpler and easier to achieve mass production compared with the micro-LEDs.

In the large-scale display equipment, it is difficult to achieve a one-time complete preparation, which often requires splicing a plurality of small displays to complete. However, in the existing large-scale spliced display equipment, it is not possible to take into account both image quality and seamless splicing technology. Thus, the image quality is greatly reduced.

### SUMMARY OF DISCLOSURE

### Technical Problems

The purpose of the present disclosure is to provide a spliced display screen, a manufacturing method thereof, and a display device, and solve the problems that the large-scale spliced display equipment in the prior art cannot take into account both the image quality and the seamless splicing technology.

### Technical Solutions

To achieve the above purposes, the present disclosure provides a spliced display screen. The spliced display screen comprises at least two display panels. Each of the display panels has a display area and a non-display area. The display area has a main display area and a flexible display area. The non-display area and the flexible display area surround the main display area.

In two adjacent display panels, the flexible display area of one of the display panels covers the non-display area of the other one of the display panels, and an edge of the flexible display area of the one of the display panels is seamlessly abutted to an edge of the non-display area of the other one of the display panels.

Further, the display panel comprises a substrate layer, a flexible layer, an array substrate, a display layer, and a driving circuit.

The substrate layer is located in the main display area and the non-display area of the display panel. The flexible layer is disposed on the substrate layer in the display area. The array substrate is disposed on the flexible layer in the display area and the substrate layer in the non-display area. The display layer is disposed on the array substrate in the display area. The driving circuit is disposed on the array substrate in the non-display area.

Further, the array substrate comprises a thin film transistor, a bonding pad, and a fan-out line.

The thin film transistor is disposed on the flexible layer in the display area. The bonding pad is disposed on the substrate layer in the non-display area. The fan-out line is connected to the thin film transistor and the boding pad.

Further, the driving circuit comprises a chip on film and a printed circuit board.

The chip on film is respectively disposed on the bonding pad. The printed circuit board is connected to the chip on film.

Further, the display panel further comprises an encapsulation layer. The encapsulation layer covers a surface of the display layer away from the array substrate.

The present disclosure further provides a manufacturing method of a spliced display screen comprising steps as follows.

At least two display panels are prepared. Each of the display panels has a display area and a non-display area. The display area has a main display area and a flexible display area. The non-display area and the flexible display area surround the main display area. In two adjacent display panels, the flexible display area of one of the display panels is adhered onto the non-display area of the other one of the display panels.

Further, the step of preparing the display panel comprises steps as follows.

A substrate layer is provided. A flexible layer is formed on the substrate layer. An array substrate is formed on the flexible layer. A display layer is formed on the array substrate in the display area. A driving circuit is formed on the array substrate in the non-display area.

Further, after the step of forming the driving circuit further comprises steps as follows. An encapsulation layer is formed on the display layer.

Further, after the step of forming the encapsulation layer further comprises steps as follows. The substrate layer in the flexible display area is peeled off by laser cutting and laser glass.

The present disclosure further provides a display device. The display device comprises the spliced display screen as described above.

### Beneficial Effects

The advantages of the present disclosure are as follows. In the spliced display screen of the present disclosure, in two adjacent display panels, the flexible display area of one of the display panels is seamless spliced and adhered onto the non-display area of the other one of the display panels. Thus, the non-display area of the other one of the display panels can also display the image, so as to achieve the large-size seamless display, thereby improving user experience. Also, the manufacturing method of the spliced display screen is simple, and the raw material thereof is easily available.

### DESCRIPTION OF DRAWINGS

FIG. 1 is a front view of a display panel according to an embodiment of the present disclosure.

FIG. 2 is a three-dimensional view of a display panel according to an embodiment of the present disclosure.

FIG. 3 is an exploded view of components of a display panel according to an embodiment of the present disclosure.

FIG. 4 is a front view of a spliced display screen according to an embodiment of the present disclosure.

FIG. 5 is a three-dimensional view of a step S20 according to an embodiment of the present disclosure.

FIG. 6 is a three-dimensional view of a step S30 according to an embodiment of the present disclosure.

FIG. 7 is a three-dimensional view of a step S40 according to an embodiment of the present disclosure.

FIG. 8 is a three-dimensional view of a step S50 according to an embodiment of the present disclosure.

FIG. 9 is a three-dimensional view of a step S60 according to an embodiment of the present disclosure.

The components in the figures are as follows. A spliced display screen 1, display panels 10, 10A, 10B, 100, and 10D, a main display area 11, a flexible display area 12, a non-display area 13, a substrate layer 100, a flexible layer 200, an array substrate 300, a thin film transistor 301, a bonding pad 302, a fan-out line 303, a display layer 400, a driving circuit 500, a chip on film 501, a printed circuit board 502, and an encapsulation layer 600.

### DETAILED DESCRIPTION OF PREFERRED EMBODIMENTS

The preferred embodiments of the present disclosure will be introduced with reference to accompanying drawings as follows to demonstrate that the present disclosure can be implemented. The embodiments of the present disclosure can completely introduce the present disclosure to those skilled in the art to make technical contents clearer and easier to understand. The present disclosure can be embodied in many different forms of the embodiments, and the scope of protection of the present disclosure is not limited to the embodiments set forth herein.

In the accompanying drawings, structurally identical components are designated by the same reference numerals, and structurally or functionally similar components throughout are designated by similar numerical reference numerals. The dimension and thickness of each component shown in the figures are arbitrarily shown. The size and thickness of each component are not limited. For the sake of clarity, the thickness of the components is exaggerated somewhat in some places in the figures.

In addition, the following description of each embodiment of the present disclosure is with reference to additional figures to illustrate specific embodiments of the present disclosure that can be implemented. The direction terms mentioned by the present disclosure, for example, “upper”, “lower”, “front”, “rear”, “left”, “right”, “inner”, “outer”, “side”, etc. are merely directions in the accompanying drawings. Thus, the direction terms used is to be better and more clearly to explain and understand the present disclosure, rather than to indicate or imply that the referred device or element must have a specific orientation, or have a construction and operation in a specific orientation, and should not be construed as the limitation of the present disclosure. In addition, the terms “first”, “second”, and “third”, etc. are used for descriptive purposes only and should not be construed to indicate or imply relative importance.

When some parts are described to be “on” another part, the part may be directly disposed on the other part; alternatively, an intervening part may exist, the parts are disposed on the intervening part, and the intervening part is disposed on the other part. When one part is described to be “installed on” or “connected to” another part, it may be understood that the parts are directly “installed” or “connected” to each other, alternatively, it is understood that one part is indirectly “installed” or “connected” to the another part through an intervening part.

An embodiment of the present disclosure provides a display device. The display device has a spliced display screen 1. The spliced display screen 1 provides a display screen for the display device. The display device may be any electronic product or component having a display function, such as a mobile phone, a notebook, or large-scale outdoor display equipment.

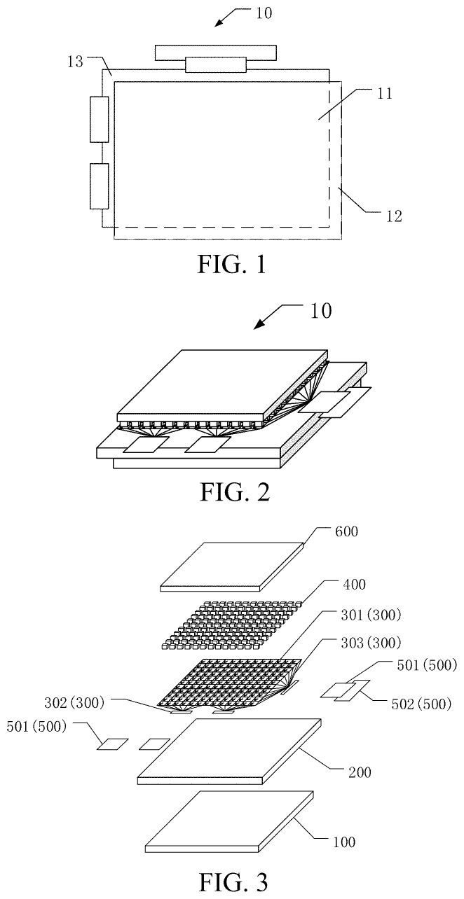

The spliced display screen 1 has four display panels 10. As shown in FIG. 1, each of the display panels 10 has a display area and a non-display area 13. The display area has a main display area 11 and a flexible display area 12. The flexible display area 12 and the non-display area 13 surround the main display area 11. The flexible display area 12 has the same size as the non-display area 13. As shown in FIG. 2 and FIG. 3, the display panel 10 comprises a substrate layer 100, a flexible layer 200, an array substrate 300, a display layer 400, and a driving circuit 500.

The substrate layer 100 is located in the main display area 11 and the non-display area 13 of the display panel 10. The substrate layer 100 is an insulating substrate, such as an insulating substrate made of glass, quartz, or other materials, which is used to protect the display panel 10.

The flexible layer 200 is disposed on the substrate layer 100 in the main display area 11, and extends into the flexible display area 12 of the display panel 10. The flexible layer 200 is made of a polyimide (PI) material. A film thickness of the flexible layer 200 is 1 to 100 micrometers. The flexible layer 200 enables the flexible display area 12 of the display panel 10 to have flexibility while ensuring the display function, so that the flexible display area 12 can be adhered onto the non-display area 13 of another of the display panels 10.

The array substrate 300 is disposed on the flexible layer 200 and the substrate layer 100, and is provided with a thin film transistor 301, a bonding pad 302, and a fan-out line 303. The thin film transistor 301 is disposed on the flexible layer 200 located in the display area, which is used to control on and off of each pixel to control the display of the screen. The thin film transistor 301 may use one of low temperature poly-silicon (LTPS) technology and indium gallium zinc oxide (IGZO) technology. The bonding pad 302 is disposed on the substrate layer 100 located in the non-display area 13, which is used to connect the driving circuit 500. The fan-out line 303 is connected to the bonding pad 302 and the thin film transistor 301, and transmits control signals of the driving circuit 500 to the thin film transistor 301.

The display layer 400 is disposed on the array substrate 300 in the display area. That is, the display layer 400 is disposed on the thin film transistor 301 of the array substrate 300, and is connected to the thin film transistor 301. The display layer 400 is formed by a plurality of mini-LED chips arranged in an array. The thin film transistor 301 in the array substrate 300 provides electric power for the display layer 400, and excites the mini-LED chips to emit light, thereby achieving display of the screen.

The encapsulation layer 600 covers a surface of the display layer 400 away from the array substrate 300, which can be made of epoxy-based, acrylic-based, or organic silicone-based resin materials. The encapsulation layer 600 is used to fix the mini-LED chip in the display layer 400 to prevent the mini-LED from falling off. Moreover, the encapsulation layer 600 protects the mini-LED chip from water and oxygen, and prevents the mini-LED chip from failure due to erosion of water and oxygen.

The driving circuit 500 is disposed on the array substrate 300 in the non-display area 13. That is, the driving circuit 500 is disposed on the bonding pad 302 of the array substrate 300. The driving circuit 500 comprises a chip on film 501 and a printed circuit board 502. The chip on film 501 is disposed on the bonding pad 302, and is connected to the thin film transistor 301 by the fan-out line 303. The chip on film 501 comprises a gate drive and a source drive. The gate drive and the source drive are respectively disposed on the bonding pads 302 on both sides of the thin film transistor 301. The printed circuit board 502 is connected to the source drive. The chip on film 501 and the printed circuit board 502 are bent and adhered onto a surface of the substrate layer 100 away from the flexible layer 200. The chip on film 501 and the printed circuit board 502 are used to provide control signals of the display screen for the thin film transistor 301.

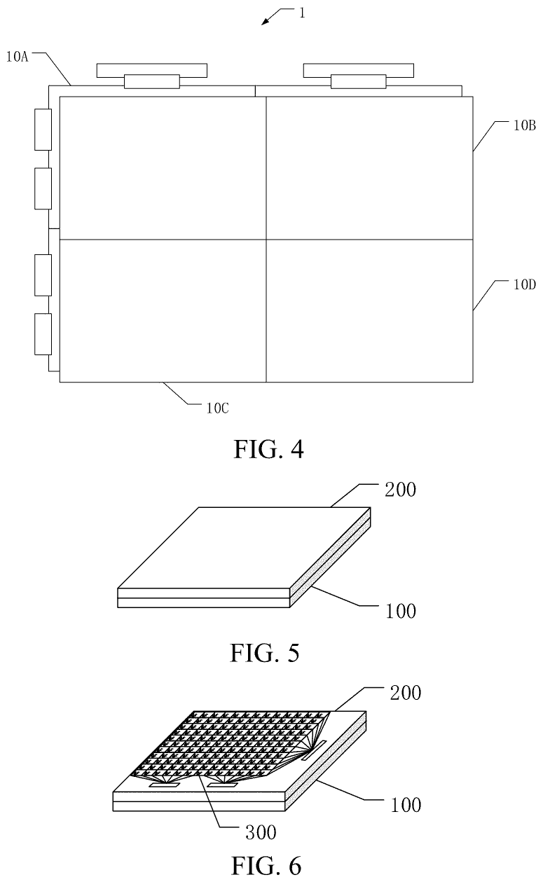

As shown in FIG. 4, the spliced display screen 1 has four display panels 10, which are respectively a display panel 10A, a display panel 10B, a display panel 100, and a display panel 10D. In the display panel 10A and the display panel 10B adjacent to each other, the flexible display area 12 of the display panel 10A covers the non-display area 13 of the display panel 10B, and an edge of the flexible display area 12 of the display panel 10A is seamlessly abutted to an edge of the non-display area 13 of the display panel 10B. As shown in FIG. 3, the driving circuit 500 of the display panel 10B is bent and adhered onto a rear surface of the display panel 10A, i.e., a surface of the substrate layer 100 of the display panel 10A away from the flexible layer 200 thereof, thereby achieving seamless splicing. Moreover, the display panel 10A and the display panel 100, the display panel 10B and the display panel 10D, and the display panel 100 and the display panel 10D all use the same splicing method as the display panel 10A and the display panel 10B, thereby achieving the large-size display.

The embodiment of the present disclosure provides the spliced display screen 1 composed of four display panels 10 by splicing. However, in other embodiments of the present disclosure, the number of the display panel 10 is not limited, and the spliced display screen 1 may be composed of five, six, or even more or less display panels 10 by splicing. In addition, in the embodiment of the present disclosure, the driving circuit 500 of the display panel 10B is bent and adhered onto the rear surface of the display panel 10A. However, in other embodiments, the display panel 10B may be bent and adhered to its own rear surface, i.e., a surface of the substrate layer 100 of the display panel 10B away from the flexible layer 200 thereof.

An embodiment of the present disclosure also provides a manufacturing method of the spliced display screen 1 comprising a step of preparing the display panel 10 and a step of adhering adjacent display panels 10.

The step of preparing the display panel 10 comprises steps as follows.

A step S10: a substrate layer 100 is provided. The substrate layer 100 may be made of inorganic materials, such as glass or quartz.

A step S20: a flexible layer 200 is formed. As shown in FIG. 5, a polyimide resin is coated on the substrate layer 100, and the polyimide resin is cured to form the flexible layer 200.

A step S30: an array substrate 300 is formed. As shown in FIG. 6, the array substrate 300 is formed on the display panel 10 by low temperature poly-silicon (LTPS) technology or indium gallium zinc oxide (IGZO) technology. The array substrate 300 comprises a thin film transistor 301, a bonding pad 302, and a fan-out line 303. The thin film transistor 301 is disposed in the display area of the display panel 10. The bonding pad 302 is disposed in the non-display area 13 of the display panel 10. The fan-out line 303 is used to connect the thin film transistor 301 and the boding pad 302.

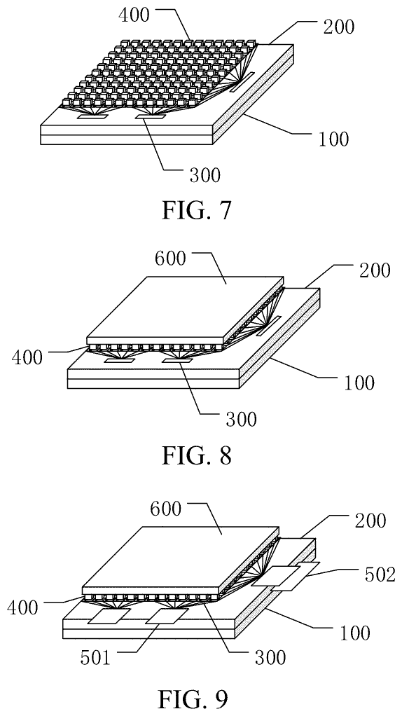

A step S40: a display layer 400 is formed. As shown in FIG. 7, the mini-LED chips are arranged in an array neatly and transferred onto the thin film transistor 301 of the array substrate 300, and P-junctions and N-junctions of the mini-LED chips are connected to the thin film transistor 301 to form the display layer 400.

A step S50: an encapsulation layer 600 is formed. As shown in FIG. 8, a layer of an encapsulation adhesive is coated on the display layer 400 in the display area and cured to form the encapsulation layer 600, so as to encapsulate and protect the mini-LED chips in the display layer 400, and prevent the mini-LED chips from falling off. The encapsulation adhesive may be made of epoxy-based, acrylic-based, or organic silicone-based resin materials.

A step S60: a driving circuit 500 is formed. As shown in FIG. 9, the driving circuit 500 is respectively and correspondingly adhered onto the bonding pad 302 of the array substrate 300. The driving circuit 500 comprises a chip on film 501 and a printed circuit board 502. The chip on film 501 is adhered and connected to the bonding pad 302, and the printed circuit board 502 is adhered and connected to the chip on film 501. The chip on film 501 comprises a source drive and a gate drive. The source drive and the gate drive are respectively connected to the bonding pads 302 located at both sides of the thin film transistor 301. The printed circuit board 502 is connected to the source drive.

A step S70: the substrate layer 100 in the flexible display area 12 of the display panel 10 is peeled off. The substrate layer 100 in the flexible display area 12 of the display panel 10 is peeled off by laser cutting and laser lift-off (LLO) to form a flexible display edge. Finally, the display panel 10 as shown in FIG. 2 is formed.

The step of adhering adjacent display panels 10 comprises steps as follows. A display panel 10A, a display panel 10B, a display panel 100, and a display panel 10D are respectively prepared by the process in the step of preparing the display panel 10. The flexible display edge of the flexible display area 12 of the display panel 10A is closely adhered onto the non-display area 13 of the display panel 10B adjacent thereto, and the flexible display area 12 of the display panel 10A is seamlessly abutted to the display area of the display panel 10B. Also, the display panel 10A is spliced with the display panel 100, and the display panel 10D is spliced with the display panel 10B and the display panel 100 using the same method, so as to form the spliced display screen 1 as shown in FIG. 4.

In the spliced display screen 1 provided by the embodiment of the present disclosure, the flexible display area 12 is formed by adding the flexible layer 200 and peeling off a portion of the substrate layer 100 in the display panel 10. Also, the flexible display area 12 in the display panel 10 is adhered onto the non-display area 13 of the other one of the display panels 10 adjacent thereto. Further, the flexible display area 12 in the display panel 10 is seamlessly abutted to the display area of the other one of the display panels 10. Thus, the large-size seamless display is achieved, thereby improving user experience. In addition, the manufacturing method of the spliced display screen 1 is simple, and the raw material thereof is easily available.

The present disclosure has been described with reference to preferred embodiments, which are only examples for illustrating the principle and application of the present disclosure. It should be understood that various modifications and variants to the present disclosure may be made by anyone skilled in the art, without departing from the scope and spirit of the present disclosure. In particular, various dependent claims and technical features described herein may be combined with one another in any different manner from the original claims. It should also be understood that the technical features described in view of a single example can also be applied to other examples.

1. A spliced display screen, comprising:
at least two display panels;
wherein each of the display panels has a display area and a non-display area, the display area has a main display area and a flexible display area, and the non-display area and the flexible display area surround the main display area;
wherein in two adjacent display panels, the flexible display area of one of the display panels covers the non-display area of the other one of the display panels, and an edge of the flexible display area of the one of the display panels is seamlessly abutted to an edge of the non-display area of the other one of the display panels.

2. The spliced display screen according to claim 1, wherein the display panel comprises:
a substrate layer located in the main display area and the non-display area of the display panel;
a flexible layer disposed on the substrate layer in the display area;
an array substrate disposed on the flexible layer in the display area and the substrate layer in the non-display area;
a display layer disposed on the array substrate in the display area; and
a driving circuit disposed on the array substrate in the non-display area.

3. The spliced display screen according to claim 2, wherein the array substrate comprises:
a thin film transistor disposed on the flexible layer in the display area;
a bonding pad disposed on the substrate layer in the non-display area; and
a fan-out line connected to the thin film transistor and the boding pad.

4. The spliced display screen according to claim 3, wherein the driving circuit comprises:
a chip on film respectively disposed on the bonding pad; and
a printed circuit board connected to the chip on film.

5. The spliced display screen according to claim 2, wherein the display panel further comprises:
an encapsulation layer covering a surface of the display layer away from the array substrate.

6. A manufacturing method of a spliced display screen, comprising steps of:
preparing at least two display panels, wherein each of the display panels has a display area and a non-display area, the display area has a main display area and a flexible display area, and the non-display area and the flexible display area surround the main display area;
wherein in two adjacent display panels, adhering the flexible display area of one of the display panels onto the non-display area of the other one of the display panels.

7. The manufacturing method according to claim 6, wherein the step of preparing the display panel comprises steps of:
providing a substrate layer;
forming a flexible layer on the substrate layer;
forming an array substrate on the flexible layer;
forming a display layer on the array substrate in the display area; and
forming a driving circuit on the array substrate in the non-display area.

8. The manufacturing method according to claim 7, wherein after the step of forming the display layer further comprises steps of: forming an encapsulation layer on the display layer.

9. The manufacturing method according to claim 8, wherein after the step of forming the driving circuit further comprises steps of: peeling off the substrate layer in the flexible display area by laser cutting and laser lift-off.

10. A display device comprises the spliced display screen according to claim 1.
